(19) United States
(12) Patent Application Publication
(10) Pub. No.: US 2011/0216515 A1
(43) Pub. Date: Sep. 8, 2011

(54) ELECTRO DEVICE EMBEDDED PRINTED CIRCUIT BOARD AND MANUFACTURING METHOD THEREOF

(75) Inventors: Jin-Won LEE, Seoul (KR); Yul-Kyo Chung, Yongin-si (KR); Doo-Hwan Lee, Euijungboo-si (KR); Seung-Hyun Sohn, Suwon-si (KR); Dae-Jung Byun, Saha-gu (KR)

(73) Assignee: SAMSUNG ELECTRO-MECHANICS CO., LTD.

(21) Appl. No.: 12/852,063

(22) Filed: Aug. 6, 2010

(30) Foreign Application Priority Data
Mar. 5, 2010 (KR) 10-2010-0019827

(51) Int. Cl. H05K 1/18; B32B 38/10; B32B 38/04

(52) U.S. Cl. 361/762; 156/247; 156/248

(57) ABSTRACT

An electro device embedded printed circuit board and a manufacturing method thereof are disclosed. In accordance with an embodiment of the present invention, an electro device embedded printed circuit board is manufactured by: adhering a first electro device on a supporting body through a face-down method; adhering a second electro device on an upper surface of the first electro device through a face-up method; stacking a pure resin layer and a reinforcing layer on an upper side of the supporting body, wherein the first electro device and the second electro device are embedded in the pure resin layer; removing the supporting body; stacking an insulation layer on a lower side of the first electro device, a reinforcing material having been impregnated in the insulation layer; and patterning a circuit on each of the reinforcing layer and the insulation layer.

### CROSS-REFERENCE TO RELATED APPLICATIONS

This application claims the benefit of Korean Patent Application No. 10-2010-0019827, filed with the Korean Intellectual Property Office on Mar. 5, 2010, the disclosure of which is incorporated herein by reference in its entirety.

### BACKGROUND

1. Technical Field

The present invention is related to an electro device embedded printed circuit board and a manufacturing method of the electro device embedded printed circuit board.

2. Description of the Related Art

In line with the new generation multi-functional compact package technologies, development of electro device embedded printed circuit boards has recently been receiving much attention. The electro device embedded boards encompass high functioning aspects in addition to the multi-functionality and compactness. This is because the electro device embedded boards can provide means for improving the reliability issue that can occur during the electrical connection of an electro device using solder ball or wire bonding used for a flip chip or a ball grid array.

In the conventional method of embedding an electro device, such as an IC, the electro device was embedded on one side of a build-up layer. This asymmetric structure was inevitably vulnerable to warpage under thermal stress. Due to the problem of the board warping toward the side on which the electro device is located under the thermal stress, it has been impossible to reduce the thickness of the electro device below a certain thickness. Moreover, the stacking material used in the printed circuit board could not be made thinner than a certain thickness due to its electrical insulating property. Therefore, the critical thickness for preventing the warpage is inherently restricted due to the property of the material.

In view of the location and thickness of embedded devices in comparison with the entire thickness or shape of the board, the conventional printed circuit board is asymmetric. Therefore, the conventional printed circuit board is under repeated thermal stress, especially in a process like soldering, which is conducted at a temperature above 200° C., and thus a possibility of warpage is present. Due to this warpage issue, the thickness of the electro device has been generally maintained above a certain thickness, and thus it has been inevitable that the entire embedded board was thick.

### SUMMARY

The present invention provides an electro device embedded printed circuit board and a manufacturing method of the electro device embedded printed circuit board that can reduce the number of layers in the printed circuit board by embedding the electro device with two layers of printed circuit board and can maximize the integration by dual-embedding the electro device. Moreover, there can be a greater degree of freedom in design, and the manufacturing process can be simplified and the manufacturing costs can be saved because there is no need for processing a cavity for embedding the electro device.

An aspect of the present invention features a manufacturing method of an electro device embedded printed circuit board. In accordance with an embodiment of the present invention, an electro device embedded printed circuit board is manufactured by: adhering a first electro device on a supporting body through a face-down method; adhering a second electro device on an upper surface of the first electro device through a face-up method; stacking a pure resin layer and a reinforcing layer on an upper side of the supporting body, wherein the first electro device and the second electro device are embedded in the pure resin layer; removing the supporting body; stacking an insulation layer on a lower side of the first electro device, a reinforcing material having been impregnated in the insulation layer; and patterning a circuit on each of the reinforcing layer and the insulation layer.

The supporting body can be a metal membrane having an adhesive layer formed on an upper surface thereof, and the supporting body can be removed by peeling off the adhesive layer.

Prior to the stacking of the pure resin layer and the reinforcing layer on the upper side of the supporting body, the pure resin layer and the reinforcing layer can be already stacked with each other. A metal membrane can be stacked on a surface of the reinforcing layer and on a surface of the insulation layer.

Prior to the adhering of the electro devices, reference holes, which are assisting means used to determine locations of the electro devices, can be formed in the supporting body. The size of the first electro device and the size of the second electro device can be different from each other.

The patterning of the circuit can include forming a blind via for directly connecting a circuit formed on a surface of the reinforcing layer with an electrode of the electro devices. The reinforcing layer and the insulation layer in which the reinforcing material is impregnated can be symmetric about the pure resin layer.

Another aspect of the present invention features an electro device embedded printed circuit board. The electro device embedded printed circuit board in accordance with an embodiment of the present invention can include: a pure resin layer; a first electro device embedded in the pure resin layer through a face-down method; a second electro device stacked on an upper surface of the first electro device and embedded in the pure resin layer through a face-up method; an insulating reinforcing layer stacked on one surface of the pure resin layer; an insulation layer stacked on the other surface of the pure resin layer and having a reinforcing material impregnated inside thereof; and a circuit formed on each of the reinforcing layer and the insulation layer.

The electro device embedded printed circuit board can also include a blind via directly connecting a circuit formed on a surface of the reinforcing layer with an electrode of the electro devices, and the reinforcing layer and the insulation layer in which the reinforcing material is impregnated can be symmetric about the pure resin layer.

The size of the first electro device and the size of the second electro device can be different from each other.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flow diagram illustrating a method of manufacturing an electro device embedded printed circuit board in accordance with an embodiment of the present invention.

FIG. 2 to FIG. 8 illustrate processes of a method of manufacturing an electro device embedded printed circuit board in accordance with an embodiment of the present invention.

### DETAILED DESCRIPTION

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the ideas and scope of the present invention. Throughout the description of the present invention, when describing a certain technology is determined to evade the point of the present invention, the pertinent detailed description will be omitted.

Terms such as “first” and “second” can be used in describing various elements, but the above elements shall not be restricted to the above terms. The above terms are used only to distinguish one element from the other.

The terms used in the description are intended to describe certain embodiments only, and shall by no means restrict the present invention. Unless clearly used otherwise, expressions in a singular form include a meaning of a plural form. In the present description, an expression such as “comprising” or “including” is intended to designate a characteristic, a number, a step, an operation, an element, a part or combinations thereof, and shall not be construed to preclude any presence or possibility of one or more other characteristics, numbers, steps, operations, elements, parts or combinations thereof.

Hereinafter, some embodiments of an electro device embedded printed circuit board and a manufacturing method thereof will be described in detail with reference to the accompanying drawings. Identical or corresponding elements will be given the same reference numerals, regardless of the figure number, and any redundant description of the identical or corresponding elements will not be repeated.

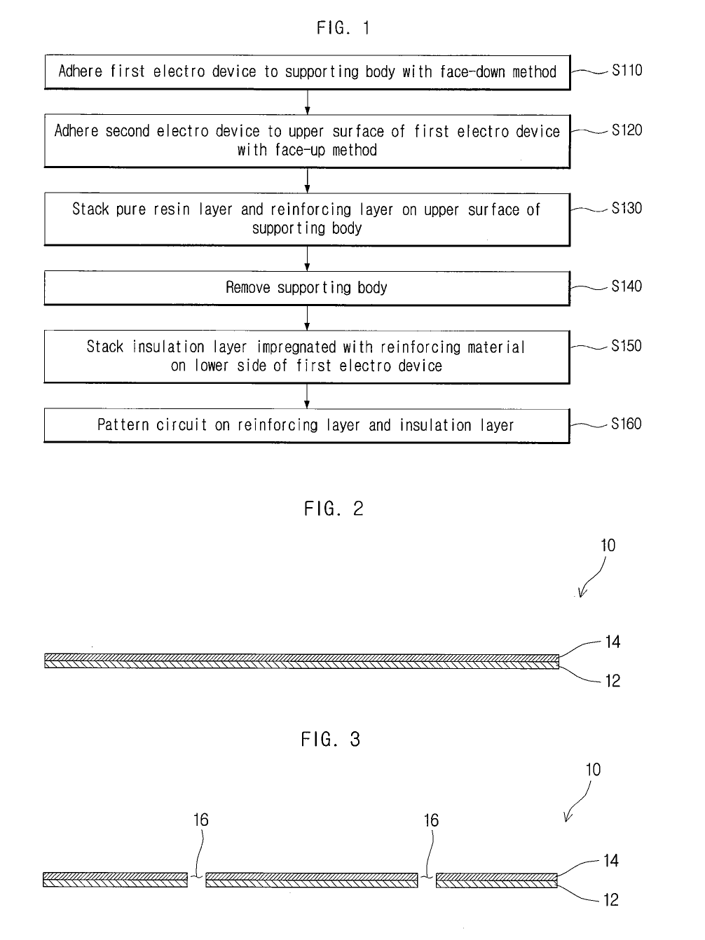

First, a manufacturing method of an electro embedded printed circuit board in accordance with an aspect of the present invention will be described. FIG. 1 is a flow diagram illustrating a method of manufacturing an electro device embedded printed circuit board in accordance with an embodiment of the present invention, and FIG. 2 to FIG. 8 are diagrams illustrating each process of the method of manufacturing an electro device embedded printed circuit board in accordance with an embodiment of the present invention. Illustrated in FIG. 2 to FIG. 8 are a supporting body 10, reference holes 16, electro devices 21, 22, electrodes 21a, 22a, an adhesive layer 23, a first insulation layer 30, a pure resin layer 32, a reinforcing layer 34, metal membranes 40, 60, a second insulation layer 50, circuits 42, 62 and blind vias 44, 64.

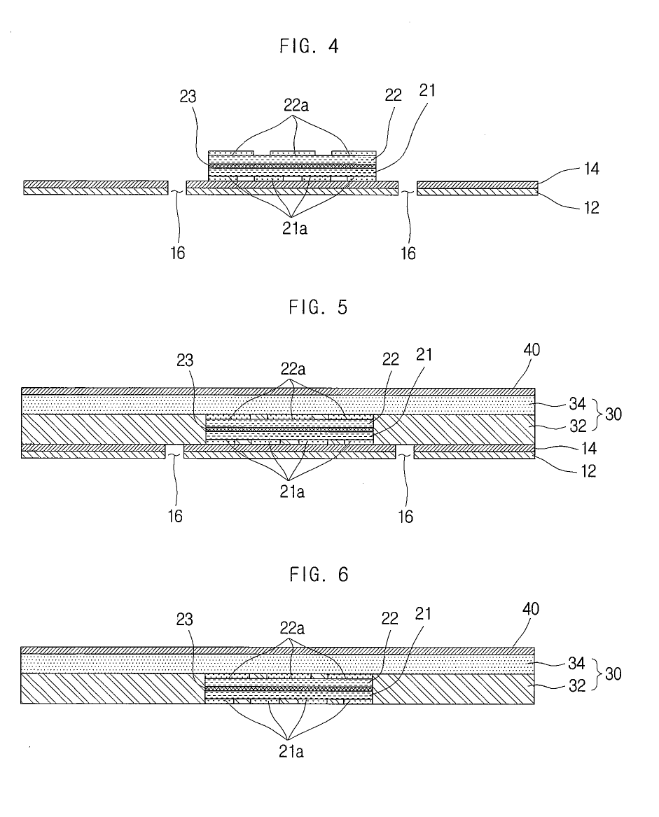

First, as illustrated in FIG. 2, the supporting body 10 is prepared. The supporting body 10, which functions to support the electro devices 21, 22 prior to embedding a first electro device 21 and a second electro device 22 (see FIG. 4) in an insulator, of the present embodiment is a metal membrane 12, for example, copper or aluminum, that is stacked with an adhesive layer 14 on an upper surface. Although the metal membrane 12 with the adhesive layer 14 formed on the upper surface thereof is used for the supporting body 10 in the present embodiment presents, it shall be appreciated that any other material can be used for the supporting body 10 as long as the material can support the electro devices 21, 22 and can be readily peeled off later.

Then, as illustrated in FIG. 3, the reference holes 16 are formed in the supporting body 10. The reference holes 16 are for helping to determine the location of the electro devices 21, 22, especially the first electro device 21, and can be formed by perforating holes in the supporting body 10. Although the present embodiment uses the reference holes 16 as means for assisting to determine the location of the electro devices 21, 22, it is also possible that other various assisting means, for example, protrusions or marks, can be used, and such assisting means can be omitted if it is deemed unnecessary.

Next, as illustrated in FIG. 4, the first electro device 21 is adhered to the supporting body 10 with a face-down method (S110), and then the second electro device 22 is adhered to an upper surface of the first electro device 21 with a face-up method (S120). In case the metal membrane 12 on which the adhesive layer 14 is formed on the surface thereof is used as the supporting body 10 as described earlier, an active surface of the first electro device, that is, a surface on which the electrode 21a is formed, can be adhered to and supported by the adhesive layer 14.

The adhesive layer 23 can be used in order to adhere the second electro device 22 to the upper surface of the first electro device 21. Although the adhesive layer 23 can be formed by coating an adhesive on or adhering an adhesive film to an inactive surface (the upper surface in the case of FIG. 4) of the first electro device 21, the second electro device 22 having the adhesive layer 23 formed thereon already in a wafer state is used in the present embodiment. That is, the second electro device 22 having the adhesive layer 23 already formed on an inactive surface (a lower surface in the case of FIG. 4) of the second electro device 22 is adhered to the upper surface of the first electro device 21. In this case, it is not required to perform a process of coating the adhesive, making the process simpler and preventing a possible contamination by excessive use of adhesive.

Although the present embodiment presents the adhesive layer 23 formed on the inactive surface of the second electro device 22, it shall be also possible that the adhesive layer 23 is formed on the inactive surface of the first electro device 21 or on the inactive surface of both the first electro device 21 and the second electro device 23.

The second electro device 22 being adhered to the upper surface of the first electro device 21 can have a different type and/or size from the first electro device 231. By vertically stacking electro devices having different types and/or sizes within one board, design freedom and integration can be greatly improved.

Next, as illustrated in FIG. 5, the first insulation layer 30 including the pure resin layer 32 and the reinforcing layer 34 is stacked on the upper surface of the supporting body 10 (S130). Here, the pure resin layer 32 is in a semi-cured state or uncured state. Through this process, the electro devices 21, 22 are embedded in the pure resin layer 32. Here, the reinforcing layer 34 refers to an insulation material in which a reinforcing material (not shown) such as glass fiber, carbon fiber, etc. are impregnated.

In the related art, the reinforcing material is impregnated inside the insulation material, which is used to embed an electro device, and there is a chance of getting electrodes of the electro device damaged by the reinforcing material impregnated inside the insulation material because the electro device is embedded using the single insulation material only.

In the present embodiment of the invention, however, by placing the pure resin layer 32, in which no reinforcing material is impregnated, where the electro devices 21, 22 are embedded, and placing the reinforcing layer 34, in which the reinforcing material is impregnated, above the pure resin layer 32, any damage of the electro devices 21, 22, more specifically, the electrodes 21a, 22a, by the reinforcing material can be obviated. In addition, by using the reinforcing layer 34 together with pure resin, the overall product rigidity can be provided.

The present embodiment uses the insulation layer 30, in which the pure resin layer 32 and the reinforcing layer 34 are already stacked. By using this first insulation layer 30, the pure resin layer 32 and the reinforcing layer 34 can be stacked at once, making the process simpler. Here, it is possible that the metal membrane 40 is stacked on a surface of the reinforcing layer 34. The metal membrane 40 stacked on the reinforcing layer 34 can be later used to form the circuit 42 (see FIG. 8).

Next, as illustrated in FIG. 6, the supporting body 10 is removed (S140). As described earlier, when a metal membrane having the adhesive layer 23 formed on the upper surface thereof is used as the supporting body 10, it is possible to remove the supporting body 10 by peeling off the adhesive layer 23. However, removing of the supporting body 10 is not restricted to the above, and it shall be evident that how the supporting body 10 is removed can be changed depending on the material, structure, etc. of the supporting body 10. Once the supporting body 10 is removed, a lower surface of the pure resin layer 32, in which the electro devices 21, 22 are embedded, is exposed, as shown in FIG. 6.

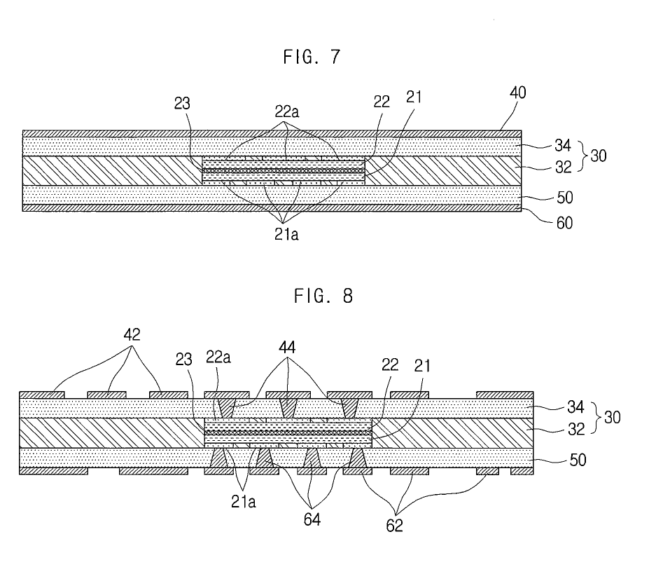

Then, as illustrated in FIG. 7, the second insulation layer 50 is stacked on a lower side of the first electro device 21 (S150). More specifically, the second insulation layer 50 is stacked on a lower surface of the pure resin layer 32, in which the electro devices 21, 22 are embedded. Here, a reinforcing material (not shown), such as glass fiber or carbon fiber, is impregnated inside the second insulation layer 50.

The second insulation layer 50 stacked on the lower surface of the pure resin layer 32 can form a symmetrical structure with the above-described reinforcing layer 34 about the pure resin layer 32. Here, the symmetrical structure includes concepts of structural symmetry having the same material and thickness as well as different materials but with different thicknesses that can prevent warpage. By implementing vertically symmetrical structure about the pure resin layer 32 in which the electro devices 21, 22 are embedded, the warpage property can be improved to increase the product reliability. Here, the metal membrane 60 can be stacked on a lower surface of the second insulation layer 50. The metal membrane 60 stacked on the lower surface of the second insulation layer 50 can be later used to form the circuit 62 (see FIG. 8).

Next, as illustrated in FIG. 8, the circuits 42, 62 are patterned on the first insulation layer 30 and the second insulation layer 50 (S160). In case finer pitch circuits are desired to be patterned, the circuits can be patterned by a plating process utilizing the metal membranes 40, 60 as a seed layer. Otherwise, the metal membranes 40, 60 can be directly etched to pattern the circuits. This can be determined at the time of designing the circuits to be patterned, and the thicknesses of the membranes 40, 60 can be also predetermined accordingly.

The circuits 42, 62, formed on the surfaces of the reinforcing layer 34 and the insulation layer 50, and the electrodes 21a, 22a of the electro devices 21, 22 can be directly connected to one another through the blind vias 44, 64. The blind vias 44, 64 can be formed by forming holes in the reinforcing layer 34 and the insulation layer 50 against where the electrodes 21a, 22a are to be formed and then filling a conductive material inside the holes by use of, for example, a plating process. By directly connecting the circuits 42, 62 and the electrodes 21a, 22a to one another, the transfer paths of signals can be prevented from being unnecessarily long. The circuit 42 formed on the surface of the reinforcing layer 34 and the circuit 62 formed on the surface of the second insulation layer 50 can be electrically connected to each other through a via hole (not shown).

Hitherto, an embodiment of the method of manufacturing an electro device embedded printed circuit board in accordance with an aspect of the present invention has been described. Hereinafter, the structure of an electro embedded printed circuit board in accordance with another aspect of the present invention will be described with reference to FIG. 8. Since the electro embedded printed circuit board according to an embodiment of the present invention can be manufactured by the above-described manufacturing method or a similar method, any redundant description will be omitted.

As illustrated in FIG. 8, the electro embedded printed circuit board in accordance with the present embodiment of the invention includes a pure resin layer 32, a first electro device 21 embedded in the pure resin layer 32 with a face-down method, a second electro device 22 adhered to an upper surface of the first electro device 21 and embedded in the pure resin layer 32 with a face-up method, an insulating reinforcing layer 34 stacked on one surface of the pure resin layer 32, an insulation layer 50 stacked on the other surface of the pure resin layer 32 and impregnated with a reinforcing material inside thereof, and circuits 42, 62 formed on the reinforcing layer 34 and the insulation layer 50.

According to the present embodiment of the invention, by placing the pure resin layer 32, in which no reinforcing material is impregnated, where the electro devices 21, 22 are embedded, and placing the reinforcing layer 34, in which the reinforcing material is impregnated, above the pure resin layer 32, any damage of the electro devices 21, 22 by the reinforcing material can be obviated. In addition, by using the reinforcing layer 34 together with pure resin, the overall product rigidity can be provided.

The second insulation layer 50 stacked on the lower surface of the pure resin layer 32 can form a symmetrical structure with the above-described reinforcing layer 34 about the pure resin layer 32. In this case, the warpage property can be improved to increase the product reliability.

Hitherto, some embodiments of the present invention have been described. However, it shall be appreciated by anyone ordinarily skilled in the art to which the present invention pertains that there can be a variety of permutations and modifications of the present invention without departing from the technical ideas and scopes of the present invention that are disclosed in the claims appended below.

A large number of embodiments in addition to the above-described embodiments are present within the claims of the present invention.

What is claimed is:

1. A method of manufacturing an electro device embedded printed circuit board, the method comprising:
adhering a first electro device on a supporting body through a face-down method;
adhering a second electro device on an upper surface of the first electro device through a face-up method;
stacking a pure resin layer and a reinforcing layer on an upper side of the supporting body, wherein the first electro device and the second electro device are embedded in the pure resin layer;
removing the supporting body;
stacking an insulation layer on a lower side of the first electro device, a reinforcing material having been impregnated in the insulation layer; and
patterning a circuit on each of the reinforcing layer and the insulation layer.

2. The method of claim 1, wherein:
the supporting body is a metal membrane having an adhesive layer formed on an upper surface thereof; and
the removing of the supporting body is performed by peeling off the adhesive layer.

3. The method of claim 1, wherein, prior to the stacking of the pure resin layer and the reinforcing layer on the upper side of the supporting body, the pure resin layer and the reinforcing layer are already stacked with each other.

4. The method of claim 3, wherein a metal membrane is stacked on a surface of the reinforcing layer and on a surface of the insulation layer.

5. The method of claim 1, further comprising, prior to the adhering of the electro devices, forming reference holes in the supporting body, the reference holes being assisting means used to determine locations of the electro devices.

6. The method of claim 1, the patterning of the circuit comprises forming a blind via for directly connecting a circuit formed on a surface of the reinforcing layer with an electrode of the electro devices.

7. The method of claim 1, wherein the reinforcing layer and the insulation layer in which the reinforcing material is impregnated are symmetric about the pure resin layer.

8. The method of claim 1, wherein at least one of a size and a type of the first electro device and the second electro device is different from each other.

9. An electro device embedded printed circuit board, comprising:
a pure resin layer;
a first electro device embedded in the pure resin layer through a face-down method;
a second electro device stacked on an upper surface of the first electro device and embedded in the pure resin layer through a face-up method;
an insulating reinforcing layer stacked on one surface of the pure resin layer;
an insulation layer stacked on the other surface of the pure resin layer and having a reinforcing material impregnated inside thereof; and
a circuit formed on each of the reinforcing layer and the insulation layer.

10. The electro device embedded printed circuit board of claim 9, further comprising a blind via directly connecting a circuit formed on a surface of the reinforcing layer with an electrode of the electro devices.

11. The electro device embedded printed circuit board of claim 9, wherein the reinforcing layer and the insulation layer in which the reinforcing material is impregnated are symmetric about the pure resin layer.

12. The electro device embedded printed circuit board of claim 9, wherein at least one of a size and a type of the first electro device and the second electro device is different from each other.
